(19) United States
(12) Patent Application Publication
(10) Pub. No.: US 2008/0000618 A1
(43) Pub. Date: Jan. 3, 2008

(54) Heat Dissipating Module

(76) Inventor: Robert Liang, Yang-Mei Town (TW)

Correspondence Address: LIN & ASSOCIATES INTELLECTUAL PROPERTY, INC., P.O. BOX 2339, SARATOGA, CA, 95070-0339, US

(21) Appl. No.: 11/427,331

(22) Filed: Jun. 28, 2006

(51) Int. Cl. H05K 7/20

(52) U.S. Cl. 165/80.3; 361/704; 257/718

(57) ABSTRACT

A heat dissipating module comprises a base having a hollowed frame, a clamping member, and a heat dissipating plate. The frame has a side wall and a post extending downwardly from each pair of faced edges thereof, the side wall has a hook at a bottom edge thereof, wherein the frame has a pivot passage at one edge thereof, and two symmetrical passages at an opposing edge and positioned at two sides of the opposed position to the pivot passage. The clamping member is a U-shaped rod having a pair of long sides and a lug folded outwardly at each of both free ends thereof. When assembling, a chip is clamped on the heat dissipating plate by the hook of the base, while middle straight segments of the long sides is pressed on a surface of the heat dissipating plate, to allow it to contact with the chip closely.

### BACKGROUND OF THE INVENTION

1. Field of the Invention

The present invention relates to a heat dissipating module, and more particularly to a heat dissipating module that allows a chip to contact tightly with a heat dissipating plate by press of a clamping member.

2. The Prior Arts

U.S. Pat. Nos. 6,153,932 and 6,644,396, both filed by the present inventor, are concerning an improvement of a base of a heat dissipating device. The structure principle of both patents is similar in that, a frame having a pair of side walls is used as the base, the side walls have hooks at ends thereof, the frame has a plurality of elastic arms extended from an edge to a center thereof, the elastic arms have lugs at free ends thereof, a heat dissipating plate to be engaged with the base has a portion fitted with the shape of the elastic arms. When assembling, heat fins are firstly inserted through the center of the frame and the frame is placed on the portion of the heat dissipating plate, and then by clamping the lugs on faced sides of a chip, and pressing the surface of the heat dissipating plate by the lugs of the elastic arms, the heat dissipating plate and the chip contact with each other closely.

The base is generally made of plastic materials. When sufficient pressure is required, the materials must be stiff enough, but this will lead to the base being lack of elasticity. Therefore, such a base can not meet simultaneously the requirements for packing chips with different thicknesses. In consideration both of the stiffness of the base materials and the elasticity and pressure-resistance of the elastic arms, it is needed to manufacture three kinds of bases for the aforementioned chips with different thicknesses, the difference of these bases is in that the length of the lugs is different, so as to be fitted with chips with different thicknesses to press the heat dissipating plate tightly.

In addition, since the difference in heights of different kinds of bases is only about 1 mm, it is difficult for them to be distinguished by naked eye, and likely to be confused or taken by mistake in storing management. Accordingly, storing management has been improved and three kinds of colors are used to designate three kinds of bases respectively. However, such an improvement will increase the cost of storing management unavoidably.

### SUMMARY OF THE INVENTION

In view of the problems occurring in related arts, the present invention designs a base, which can be fitted simultaneously with various chips with different thickness, and provide tight contact between the chips and heat dissipating plates.

In order to achieve the object of the present invention, a heat dissipating module is provided, which comprises a base, an elastic champing member and a heat dissipating plate.

The base has a hollowed frame, a side wall extending downwardly and vertically from each of a pair of opposing edges of the frame, a hook protruding from a bottom edge of the side wall, and a post extending downwardly and vertically from each of another pair of opposing edges of the frame. The improvement comprises that the frame has a pivot passage provided at one edge, and two symmetrical passages provided at an opposing edge and positioned at two sides of the opposed position to the pivot passage.

The clamping member is a U-shaped rod. A pair of long sides of the rod has a bulge at each of the head ends and tail ends thereof, the bulge has a height difference with a middle segment of the rod, and the pair of the bulges has a lug formed perpendicularly at each of free ends thereof.

When assembling the elastic clamping member with the base, firstly one long side passes through the pivot passage such that a perpendicular segment between the two long sides is received within the pivot passage, and the two long sides are parallel each other and cross the faced edges of the frame, and then the lug is received within the passage. Thereafter, a heat dissipating plate having heat dissipating fins or columns is clamped between the two side walls of the base, at the same time the two long sides of the clamping member passes through a gap between adjacent fins of the heat dissipating plate, and then the assembling of the heat dissipating module is accomplished.

In another embodiment of the structure of the base, the two faced edges of the frame each has a notch, the depth of which is extended to a top surface of the post. One notch is provided with the pivot passage therein, and another notch has a hole extended inwardly in each of faced end faces thereof, which are formed as the passages. The perpendicular segment between the two long sides of the clamping member also passes through the pivot passage, and the two lugs are engaged with the holes respectively.

When engaging a chip on a circuit board with the present heat dissipating module, firstly snapping one hook with a bottom edge of the chip, snapping another hook with an opposed edge of the bottom edge, and placing the chip below the base and contacting with a bottom surface of the heat dissipating plate. When the chip is pressed, the heat dissipating plate will move upwardly, such that middle straight segments of the long sides of the clamping member are pressed onto the heat dissipating plate, and passed through gaps between the pluralities of heat dissipating columns.

By the engagement of the clamping member and the base according to the present invention, various chips with different thicknesses can be contained simultaneously, and sufficient pressure can be provided to contact the heat dissipating plate and the chip closely and tightly. Accordingly, in one aspect, the costs of storing management can be reduced, and in another aspect, since the diameter of the rod of the clamping member is very small, it will only take up the gap between the heat dissipating fins (heat dissipating columns), which relatively increases the heat dissipating area. While the conventional base has elastic arms, in order to leave a space in the heat dissipating plate used for mounting the elastic arms, some heat dissipating fins (heat dissipating columns) must be sacrificed for placing the elastic arms, which will decrease the heat dissipating area.

### BRIEF DESCRIPTION OF THE DRAWINGS

The present invention will be apparent to those skilled in the art by reading the following detailed description of preferred embodiments thereof, with reference to the attached drawings, in which:

FIG. 1 is an exploded view of a heating dissipating module according to the present invention;

FIG. 2 is an embodiment of the heat dissipating module and a chip assembled according to the present invention;

FIG. 3 is a perspective view showing a partial assembly according to an embodiment of the present invention;

FIG. 4 is a perspective view showing a partial assembly according to another embodiment of the present invention;

FIG. 5 is a sectional view showing the heat dissipating module of the present invention used for assembled with a chip with a larger thickness; and

FIG. 6 shows a clamping member according to another embodiment of the present invention.

### DETAILED DESCRIPTION OF THE PREFERRED EMBODIMENT

Now, preferred embodiments of the present invention will be described in detail with reference to the accompanying drawings, such that it can be carried out by those skilled in the art from reading.

In order to prevent an electronic component such as a chip on a circuit board or a CPU from being burned due to over heat, it is desired to provide an excellent clamping member for clamping firmly a heat dissipating plate (together with a fan) with the electronic component, to achieve good effect of heat dissipating.

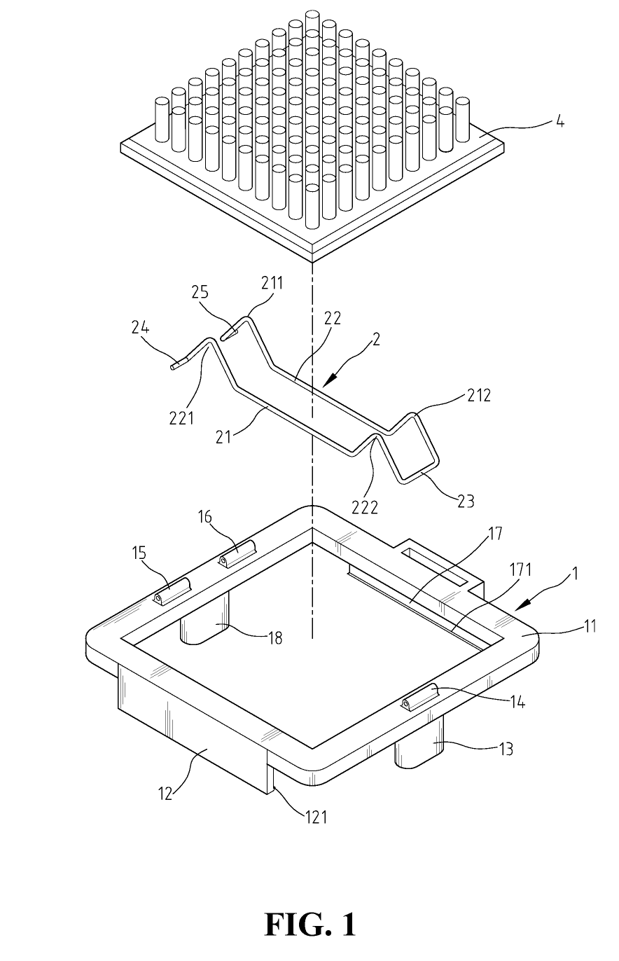

Referring to FIG. 1, a heat dissipating module according to the present invention mainly comprises a base 1, an elastic clamping member 2, and a heat dissipating plate 4.

The base 1 has a rectangular hollowed frame 11. Two side walls 12, 17 are extending perpendicularly and downwardly from a pair of opposing sides of the frame 11 respectively, and each has a length shorter than the sides of the frame. Two hooks 121, 171 are protruding perpendicularly and inwardly from bottom edges of the side walls 12, 17. Two posts 13, 18 having elliptical end surfaces are extending perpendicularly and downwardly from the other pair of opposing sides of the frame 11 at their central portions respectively. The space defined by the two posts 13, 18 and the two side walls 12, 17 has identical shape with the hollowed space of the frame 11. A pivot passage 14 is provided on a surface of the frame 11 opposing to the post 13, and two passages 15, 16 are provided on the surface of the frame 11 opposing to the post 18. The pivot passage 14 and the passages 15, 16 are protruding upwardly from the surface of the frame 11, and each is shaped as a tube having an approximate circular end face. However, the tubes also can be designed to have a half-circular end face, or a concaved end face with one side opened. The passages 15, 16 are positioned at two sides of the corresponding position at the opposing side of the pivot passage 14. The passages 15, 16 and the pivot passage 14 are integrally formed with the base 11.

The elastic clamping member 2 has two parallel long sides 21, 22, whose head end and tail end are folded as two pairs of symmetrical triangles 221, 222, 211, 212. The two folded long sides 21, 22 are symmetrical each other, wherein the ends of the two triangles 222, 212 are folded continuously so as to form a perpendicular segment therebetween, which results in a distance between the two long sides 21, 22 and makes the rod integrally be U-shaped. The free ends of the two triangles 221, 211 are folded towards two opposite sides respectively so as to form two lugs 24, 25 which have an approximate right angle with the two triangles 221, 211. Such an arrangement is designed that the two long sides 21, 22 have elastic in relation to each other, that is to say, the two long sides 21, 22 can move closer and return back original status. In addition, since there are height differences between the triangles 221, 222, 211, 212 and the long sides 22, 21, the long sides 21, 22 have resilience of being pressed down or pulled up.

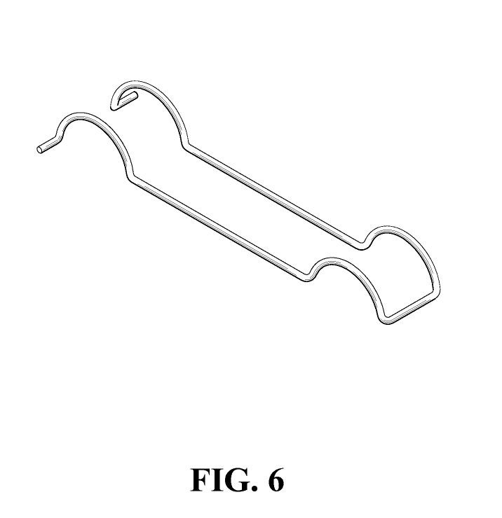

Besides the shape as shown in FIG. 1, the elastic clamping member 2 can also be shaped as shown in FIG. 6, wherein the triangles 221, 222, 211, 212 are changed to be arc or other shapes, and the rod used as the elastic component can also be a plate with rectangular end face (not shown) or other geometrical bodies.

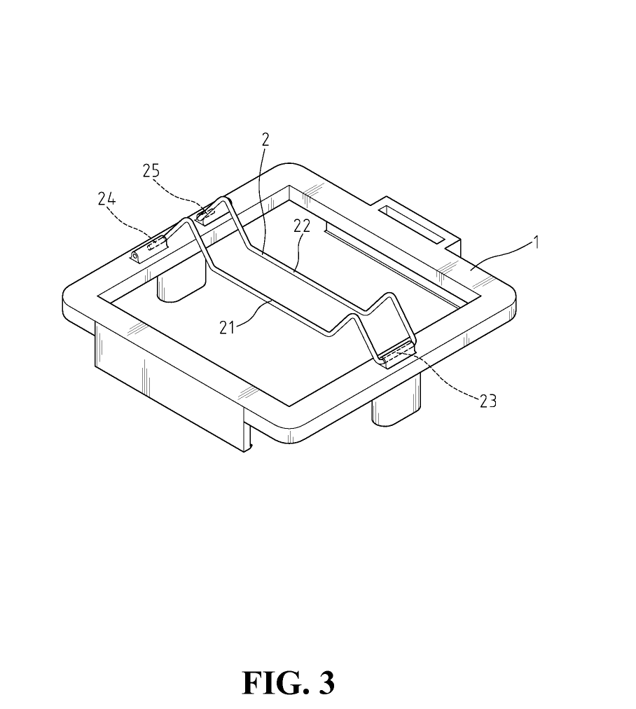

The assembling process is shown in FIGS. 1-3. The long side 22 of the clamping member 2 is traversing through the pivot passage 14 until the perpendicular segment 23 is received within the pivot passage 14. At the same time, the two long sides 21, 22 will be at two sides of the pivot passage 14, and cross the two sides of the frame 1 in parallel. Then, the two lugs 24, 25 are respectively inserted into the two passages 15, 16. When the clamping member 2 is combined with the base 1, the heat dissipating plate 4 is mounted onto the base 1 between two sides 17, 12 from below. The heat dissipating plate 4 can not release due to the stop of the hooks 121, 171. At the same time, the two long sides 21, 22 of the clamping member 2 is inserted through a gap between adjacent fins of the heat dissipating plate 4, and as such the assembly of the heat dissipating module is accomplished.

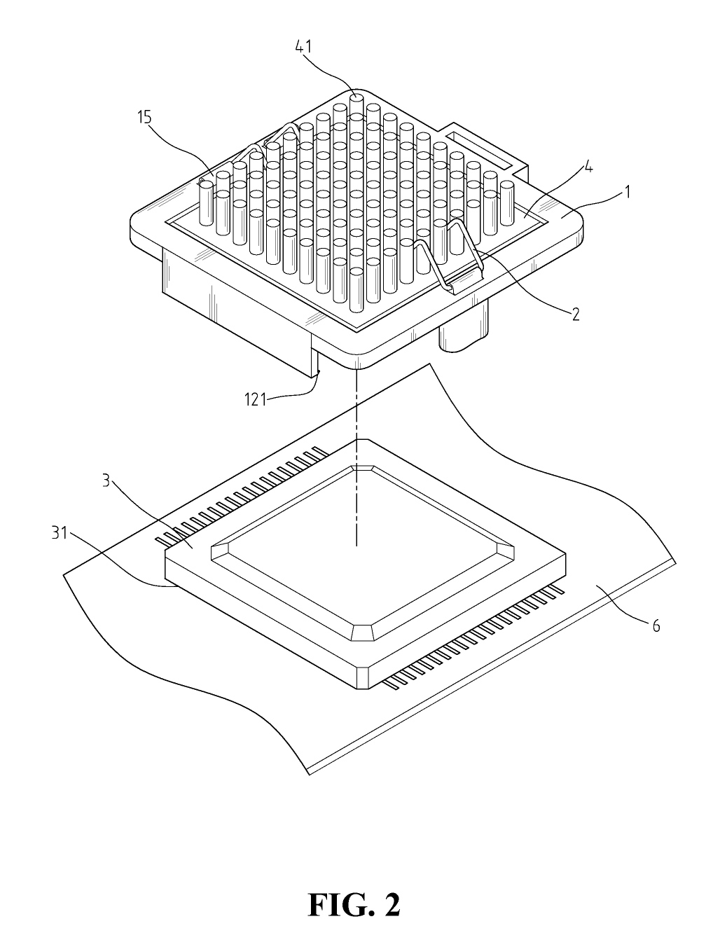

Referring to FIG. 2, the heat dissipating module according to the present invention is assembled with a chip 3 on a circuit board 6 in the following process. Firstly, snapping the hook 121 with a bottom edge 31 of the chip 3, snapping the hook 171 with a bottom edge (not shown) opposing to the bottom edge 31, and making the lower surface of the heat dissipating plate 4 contact closely with the chip 3. While the base 1 is pressed into the chip 3, the heat dissipating plate 4 will move upwardly, resulting in the surface of the heat dissipating plate 4 contacting closely with the two long sides 21, 22 of the clamping member 2. And then, since the wire diameter of the clamping member 2 is very small, the two long sides 21, 22 will be within the gap among heat dissipating columns 41, while one inclined side of each of the triangles 221, 222, 211, 222 contacts the side of the frame, and another inclined side crosses the surface of the heat dissipating plate 4.

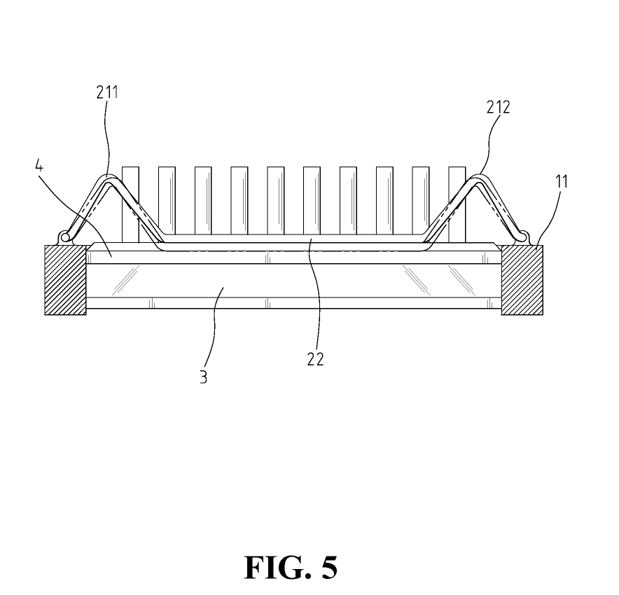

In consideration of the fact that encapsulations of chips generally have various thicknesses, the clamping member 2 of the present invention can be used for chips 3 with various thicknesses. As shown in FIG. 5, when the heat dissipating module of the present invention is used for a thicker chip 3, the heat dissipating plate 4 will be pushed to a high level, and the surface thereof will be higher than the surface of the frame 11. At this time, the two long sides 21, 22 of the snapped clamping member 2 can be pushed upwardly and elastically due to the fact that there is a height difference between the two long sides 21, 22 and the triangles 221, 222, 211, 212. Then as compared with the two long sides 21, 22 being used for a thinner chip, the level of the two long sides 21, 22 will become higher, and the angles of the triangles 221, 222, 211, 212 also become bigger.

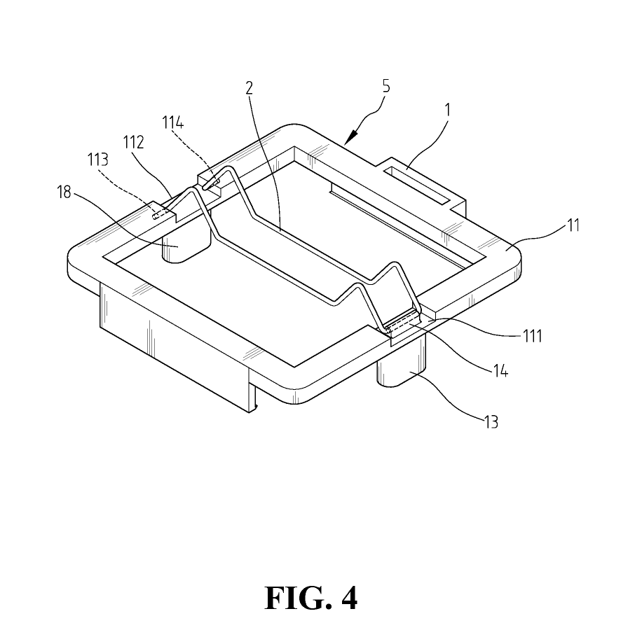

Referring to FIG. 4, another embodiment of the pivot passage and the passages is shown. In this embodiment, two notches 111, 112 are provided on the two faced edges of the frame 11 respectively. The depth of these notches 111, 112 is extended to the top surfaces of the posts 13, 18. The pivot passage 14 is disposed within the notch 111, and is shaped as a tube having an approximate circular or half-circular end face, or a concaved end face with one side opened. Two holes are extended inwardly towards the two opposing faces of the notch 112 respectively, which are parallel to the side of the frame and used as the passages 113, 114 to replace the passages 15, 16 in the first embodiment. The clamping member 2 engages with the base in the same manner as in the first embodiment substantively, except that the two lugs 24, 25 are inserted into the passages 113, 114 respectively.

Due to the characteristic of elasticity, the present invention can be applied to chips or heat dissipating plates with any thicknesses. The pressure of the clamping member 2 applied to the heat dissipating plate 4 is sufficient to keep the chip 3 to contact with the heat dissipating plate 4 closely. In addition, because the elastic clamping member 2 is a rod, which can be received within the gap between the heat dissipating columns (fins) no matter the heat dissipating columns or fins are used, it is not necessary to sacrifice some heat dissipating columns to enlarge the contact area in order to contact the rod with the surface of the heat dissipating plate 4.

Although the present invention has been described with reference to the preferred embodiments thereof, it is apparent to those skilled in the art that a variety of modifications and changes may be made without departing from the scope of the present invention which is intended to be defined by the appended claims.

What is claimed is:

1. A heat dissipating module, comprising:
a base having a hollowed frame, a side wall extending downwardly and vertically from each of a pair of opposing edges of the frame, a hook protruding from a bottom edge of the side wall, and a post extending downwardly and vertically from each of another pair of opposing edges of the frame, wherein the improvement comprises that the frame has a pivot passage provided at one edge, and two symmetrical passages provided at an opposing edge and positioned at two sides of the opposed position to the pivot passage;
a clamping member being a U-shaped rod having a pair of symmetrical long sides, wherein the long sides have a bulge at each of the head ends and tail ends thereof, the bulge has a height difference with a middle segment of the long side, the pair of the bulges have a perpendicular segment therebetween and a lug formed perpendicularly at each of free ends thereof, the perpendicular segment is received within the pivot passage, the lug is received within the passage, and the two long sides cross the faced edges of the frame; and
a heat dissipating plate having heat dissipating fins or columns, which is clamped between the side walls, and the two long sides of the clamping member are inserted through a gap between adjacent fins.

2. The heat dissipating module as claimed in claim 1, wherein the pivot passage and the passages are tubes having circular end faces, which are protruded from the upper surface of the edges of the frame and are parallel with the edges.

3. The heat dissipating module as claimed in claim 1, wherein the pivot passage and the passages are tubes having half-circular end faces, which are protruded from the upper surface of the edges of the frame and are parallel with the edges.

4. The heat dissipating module as claimed in claim 1, wherein the pivot passage and the passages are tubes having concaved end faces with one side opened, which are protruded from the upper surface of the edges of the frame and are parallel with the edges.

5. The heat dissipating module as claimed in claim 1, wherein the two edges of the frame from which the posts extends each has a notch faced to each other, the depth of the notch is extended to a top surface of the post, one notch is provided with the pivot passage shaped as a tube which is positioned on a bottom of the notch and parallel with the edge of the frame, another notch has a hole extended inwardly in each of faced end faces thereof, which is formed as the passage and parallel with the edge of the frame.

6. The heat dissipating module as claimed in claim 5, wherein the pivot passage is a concaved tube having circular end faces.

7. The heat dissipating module as claimed in claim 5, wherein the pivot passage is a concaved tube having half-circular end faces.

8. The heat dissipating module as claimed in claim 5, wherein the pivot passage is a tube having concaved end faces with one side opened.

9. The heat dissipating module as claimed in claim 1, wherein the end faces of the rod are circular, and the bulge of the rod is triangular-profiled.

10. The heat dissipating module as claimed in claim 1, wherein the end faces of the rod are rectangular, and the bulge of the rod is arc-profiled.
